(19) United States
(12) Patent Application Publication
(10) Pub. No.: US 2018/0241371 A1
(43) Pub. Date: Aug. 23, 2018

(54) PIEZOELECTRIC DEVICE

(71) Applicant: NIHON DEMPA KOGYO CO., LTD., Tokyo (JP)

(72) Inventors: Masazumi KUBOTA, Saitama (JP); Yoshihiro WATANABE, Saitama (JP)

(73) Assignee: NIHON DEMPA KOGYO CO., LTD., Tokyo (JP)

(21) Appl. No.: 15/892,380

(22) Filed: Feb. 8, 2018

(30) Foreign Application Priority Data
Feb. 21, 2017 (JP) 2017-029907
May 23, 2017 (JP) 2017-101465

(51) Int. Cl. H03H 9/13; H03H 9/02; H03H 9/05; H03H 9/10; H03H 9/19

(52) U.S. Cl. CPC H03H 9/132; H03H 9/02102; H03H 9/19; H03H 9/0509; H03H 9/1021; H03H 9/0519

(57) ABSTRACT

A piezoelectric device includes a piezoelectric substrate, a first excitation electrode, a first extraction electrode, a second excitation electrode, a second extraction electrode, a container, and a first unnecessary vibration suppression electrode, and/or a second unnecessary vibration suppression electrode. The first unnecessary vibration suppression electrode is disposed on a region of the first principal surface opposed to the second extraction electrode, at a region separated from the first excitation electrode by a distance d1. The first unnecessary vibration suppression electrode has an electric potential identical to the second excitation electrode. The second unnecessary vibration suppression electrode is disposed on a region of the second principal surface opposed to the first extraction electrode, at a region separated from the second excitation electrode by a distance d2. The second unnecessary vibration suppression electrode has an electric potential identical to the first excitation electrode.

### CROSS-REFERENCE TO RELATED APPLICATIONS

This application is based on and claims priority under 35 U.S.C. § 119 to Japanese Patent Application No. 2017-101465, filed on May 23, 2017, and Japanese Patent Application No. 2017-029907, filed on Feb. 21, 2017, and the entire content of which is incorporated herein by reference.

### TECHNICAL FIELD

This disclosure relates to a piezoelectric device such as a piezoelectric resonator and a piezoelectric oscillator vibrating at a thickness-shear vibration mode.

### DESCRIPTION OF THE RELATED ART

A piezoelectric device such as a crystal resonator and a crystal controlled oscillator has been heavily used in various kinds of electronic equipment for the purpose of, for example, selection and control of a frequency. There has been provided a typical piezoelectric device that uses a thickness-shear vibration. In terms of the crystal resonator, such piezoelectric device is a doubly-rotated cut crystal resonator typified by an AT-cut crystal resonator or an SC-cut crystal resonator.

With the piezoelectric device using the thickness-shear vibration, a main vibration and a vibration other than the main vibration, namely, an unnecessary vibration, are present. If both are combined, properties of the piezoelectric device deteriorate. As a technique to reduce the unnecessary vibration, for example, the related art section in Japanese Unexamined Patent Application Publication No. 2003-309446 (hereinafter referred to as Patent Literature 1) discloses a technique that applies an adhesive over a region where an excitation electrode is not formed on a principal surface of a crystal element, so as to add the weight by the adhesive to reduce unnecessary vibrations.

Meanwhile, a request for improvement in a property of a piezoelectric device has increased more and more. For example, the following is requested for a high-accuracy temperature compensation type crystal controlled oscillator (TCXO). A frequency versus temperature characteristic of a crystal resonator itself is measured, this temperature characteristic is approximated by a high degree function, for example, from fourth-order to seventh-order, and a frequency is compensated in accordance with this approximation formula to flat the temperature characteristic output from the TCXO as much as possible. To meet such request, an approximated curve of the frequency versus temperature characteristic of the crystal resonator itself where a coefficient of correlation is “1” is ideal. However, actually, a phenomenon where the frequency is out of the approximated curve at a large number of temperatures, so-called Frequency dips, occurs. Even if the ideal state is impossible for the frequency versus temperature characteristic of the crystal resonator used for the high-accuracy TCXO, the Frequency dips are preferably within ±0.2 ppm, more preferably within ±0.15 ppm in an environmental temperature range planned to be used, for example, in a range of −40° C. to +85° C.

For such demand, in the method of Patent Literature 1, a variation in accuracy to apply an adhesive cannot be ignored, possibly deteriorating the property of the piezoelectric device on the contrary. Taking an advancement of downsizing of the piezoelectric device more and more into consideration, an advent of a technique that can handle the demand has been desired.

A need thus exists for a piezoelectric device which is not susceptible to the drawback mentioned above.

### SUMMARY

According to an aspect of this disclosure, there is provided a piezoelectric device that vibrates in a thickness-shear vibration mode. The piezoelectric device includes a piezoelectric substrate, a first excitation electrode, a first extraction electrode, a second excitation electrode, a second extraction electrode, and a container. The piezoelectric device further includes a first unnecessary vibration suppression electrode and/or a second unnecessary vibration suppression electrode. The first excitation electrode is disposed on a first principal surface of the piezoelectric substrate. The first extraction electrode is extracted from the first excitation electrode to an end of the piezoelectric substrate. The second excitation electrode is disposed on a second principal surface opposed to the first principal surface of the piezoelectric substrate. The second extraction electrode is extracted from the second excitation electrode to another end of the piezoelectric substrate. The container houses the piezoelectric substrate. The first unnecessary vibration suppression electrode is disposed on a region of the first principal surface opposed to the second extraction electrode. The first unnecessary vibration suppression electrode is disposed at a region separated from the first excitation electrode by a distance d1. The first unnecessary vibration suppression electrode has an electric potential identical to the second excitation electrode. The second unnecessary vibration suppression electrode is disposed on a region of the second principal surface opposed to the first extraction electrode. The second unnecessary vibration suppression electrode is disposed at a region separated from the second excitation electrode by a distance d2. The second unnecessary vibration suppression electrode has an electric potential identical to the first excitation electrode. In a case where the first unnecessary vibration suppression electrode and the second unnecessary vibration suppression electrode are both provided, the distance d1 and the distance d2 are identical or different.

### BRIEF DESCRIPTION OF THE DRAWINGS

The foregoing and additional features and characteristics of this disclosure will become more apparent from the following detailed description considered with reference to the accompanying drawings, wherein:

FIG. 1A, FIG. 1B, and FIG. 1C are explanatory drawings of a piezoelectric device 10 according to a first embodiment of a first aspect;

FIG. 2A and FIG. 2B are explanatory drawings of Working Examples of the first aspect;

FIG. 3A and FIG. 3B are explanatory drawings of Working Example and Comparative Example of the first aspect;

FIG. 4 is an explanatory drawing of a piezoelectric device 30 according to a second embodiment of the first aspect;

FIG. 5A and FIG. 5B are explanatory drawings of a piezoelectric device 40 according to a third embodiment of the first aspect;

FIG. 6A and FIG. 6B are explanatory drawings of a piezoelectric device 50 according to a fourth embodiment and a piezoelectric device 60 according to a fifth embodiment of the first aspect;

FIG. 7 is an explanatory drawing of the embodiment of the first aspect and is a drawing describing a relationship between a distance between a suppression electrode and an excitation electrode and a loss in a crystal unit;

FIG. 8 is an explanatory drawing of an embodiment of a second aspect;

FIG. 9 is an explanatory drawing of an embodiment of a third aspect;

FIG. 10 is an explanatory drawing of an embodiment of a fourth aspect; and

FIG. 11A, FIG. 11B, and FIG. 11C are explanatory drawings of embodiments of a fourth aspect.

### DETAILED DESCRIPTION

The following describes embodiments of respective aspects of this application with reference to the drawings. Respective drawings used in the description are merely illustrated schematically for understanding these aspects. In each drawing used in the description, like reference numerals designate corresponding or identical elements, and therefore such elements will not be further elaborated here in some cases. Shapes, dimensions, materials, and a similar factor described in the following embodiments are merely preferable examples within the scope of the aspects. Therefore, the aspects are not limited to only the following embodiments.

### 1. First Embodiment of First Aspect

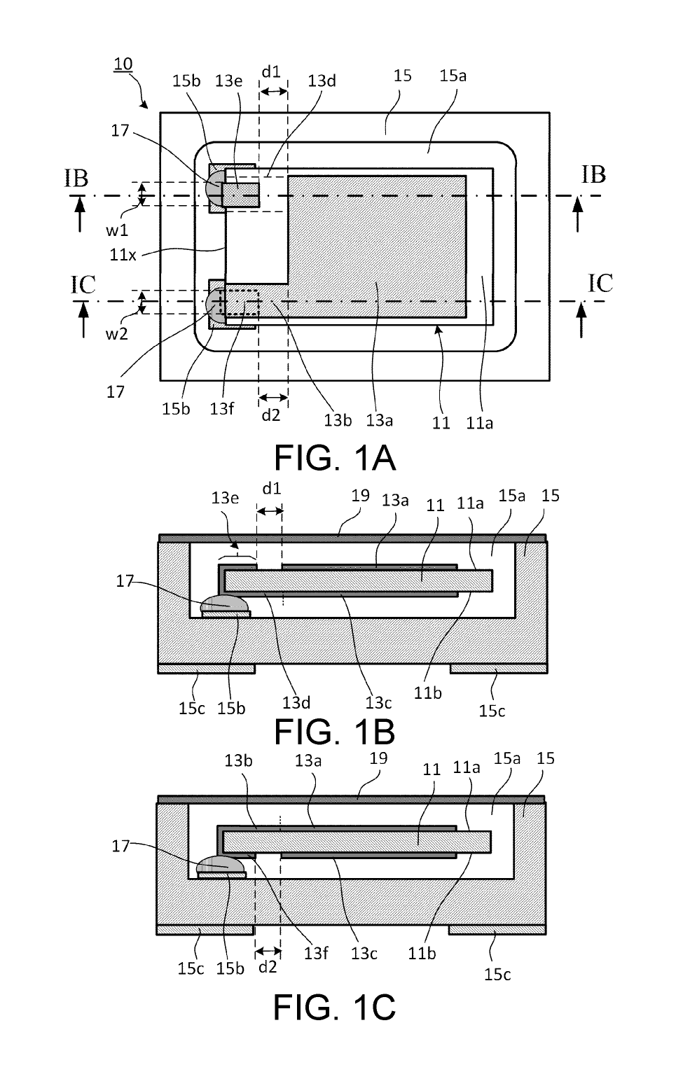

FIG. 1A to FIG. 1C are drawings describing a piezoelectric device 10 according to the first embodiment of the first aspect. Especially, FIG. 1A is a plan view of the piezoelectric device 10, FIG. 1B is a cross-sectional view taken along a line IB-IB in FIG. 1A, and FIG. 1C is a cross-sectional view taken along a line IC-IC in FIG. 1A. FIG. 1A omits an illustration of a lid member 19 illustrated in FIG. 1B and FIG. 1C.

This piezoelectric device 10 includes a piezoelectric substrate 11, a first excitation electrode 13a, a first extraction electrode 13b, a second excitation electrode 13c, a second extraction electrode 13d, a first unnecessary vibration suppression electrode 13e, a second unnecessary vibration suppression electrode 13f, a container 15, a conductive adhesive 17, and the lid member 19. The following describes these structural components.

The piezoelectric substrate 11 ensures a thickness-shear vibration and is various kinds of piezoelectric substrates such as a quartz substrate, typically an AT-cut quartz substrate or a doubly-rotated cut quartz substrate typified by an SC-cut. With this embodiment, the piezoelectric substrate 11 is an AT-cut quartz substrate whose planar shape is a square shape, specifically a rectangular shape. This piezoelectric substrate 11 has a first principal surface 11a and a second principal surface 1 lb opposed to the first principal surface 11a.

The first excitation electrode 13a is disposed at a part of a region including a central region of the first principal surface 11a on the piezoelectric substrate 11. The first extraction electrode 13b is extracted from a part of the first excitation electrode 13a of the piezoelectric substrate 11 to one end side of a first-side 11x of the piezoelectric substrate 11. The second excitation electrode 13c is disposed at a part of a region including a central region of the second principal surface 11b on the piezoelectric substrate 11. The second extraction electrode 13d is extracted from a part of the second excitation electrode 13c of the piezoelectric substrate 11 to the other end side of the first-side 11x of the piezoelectric substrate 11.

The first unnecessary vibration suppression electrode 13e is disposed on a region of the first principle surface 11a opposed to the second extraction electrode 13d of the second principal surface 11b, and the first unnecessary vibration suppression electrode 13e is disposed on a region separated from the first excitation electrode 13a by a distance d1. Besides, this first unnecessary vibration suppression electrode 13e is electrically connected to the second extraction electrode 13d via a side surface of the piezoelectric substrate 11. In view of this, the first unnecessary vibration suppression electrode 13e has an electric potential identical to the second excitation electrode 13c. Here, let alone the completely identical electric potential, the identical electric potentials may have an electric potential difference at which a voltage drop caused by a wiring length of, for example, the second extraction electrode 13d occurs (the same applies to the following second unnecessary vibration suppression electrode 130. While a width w1 of the first unnecessary vibration suppression electrode 13e is configured as a width according to the design, the width w1 is preferably the same extent to a width of the second extraction electrode 13d.

The second unnecessary vibration suppression electrode 13f is disposed on a region of the second principle surface 11b opposed to the first extraction electrode 13b of the first principal surface 11a, and the second unnecessary vibration suppression electrode 13f is disposed on a region separated from the second excitation electrode 13c by a distance d2. Besides, this second unnecessary vibration suppression electrode 13f is electrically connected to the first extraction electrode 13b via a side surface of the piezoelectric substrate 11. In view of this, the second unnecessary vibration suppression electrode 13f has an electric potential identical to the first excitation electrode 13a. The distance d2 may be identical to or different from the distance d1 of the first unnecessary vibration suppression electrode 13e and is configured to be a distance appropriate to suppress the unnecessary vibration. While a width w2 of the second unnecessary vibration suppression electrode 13f is configured as a width according to the design, the width w2 is preferably the same extent to the width of the second extraction electrode 13d. This width w2 may be identical to or different from the width w1.

These first excitation electrode 13a, first extraction electrode 13b, second excitation electrode 13c, second extraction electrode 13d, first unnecessary vibration suppression electrode 13e, and second unnecessary vibration suppression electrode 13f can be batch-formed on the piezoelectric substrate 11 using a well-known plating frame technique and film forming technique, or photolithography technique and film forming technique. Taking the unnecessary vibration suppression effect into consideration, film thicknesses of the first and the second unnecessary vibration suppression electrodes 13e and 13f may differ from film thicknesses of the excitation electrodes and the extraction electrodes depending on the design (this point will be described later in detail in an embodiment of a second aspect).

In this case, the container 15 includes a depressed portion 15a, connection pads 15b, and external terminals 15c. The depressed portion 15a has a shape and a size to house the piezoelectric substrate 11. The connection pads 15b are disposed at predetermined positions at the depressed portion 15a of the container 15 such that the piezoelectric substrate 11 can be held at near both ends of the first-side 11x of the piezoelectric substrate 11. The external terminals 15c are disposed on an outer bottom surface of the container 15. The connection pads 15b and the external terminals 15c are electrically connected with a via-wiring (not illustrated) disposed in the container 15.

This piezoelectric substrate 11 is electrically and mechanically connected and fixed to the connection pads 15b of the container 15 at positions near both ends of the first-side 11x and end portions of the first and the second extraction electrodes 13b and 13d with the conductive adhesive 17, typically a silicone-based conductive adhesive. The lid member 19 seals this container 15. This piezoelectric device 10 is equivalent to one where the piezoelectric substrate 11 is connected and fixed to the container by a cantilever structure.

### 2. Working Example and Comparative Example of First Aspect

The following describes effects brought by the unnecessary vibration suppression electrodes 13e and 13f with reference to experimental results.

Piezoelectric devices of Working Example with the structure described using FIG. 1A to FIG. 1C and piezoelectric devices of Comparative Example where the structure was not employed were prototyped. In detail, the piezoelectric devices of Working Example 1 that included the first and the second unnecessary vibration suppression electrodes 13e and 13f and had the distance d1=d2=0.17 mm, the piezoelectric devices of Working Example 2 that included the first and the second unnecessary vibration suppression electrodes 13e and 13f and had the distance d1=d2=0.12 mm, and the piezoelectric devices of Comparative Example not including the unnecessary vibration suppression electrode were prototyped. The oscillation frequency was set to 38.8 MHz, and the number of samples was 60 pieces for each.

Next, a frequency versus temperature characteristic of all the three kinds of respective piezoelectric devices was measured in a range of −40° C. to 85° C. in increments of 5° C. Furthermore, an approximate equation for quartic function regarding the measured temperature characteristics of the respective piezoelectric devices was obtained using a least square method. Furthermore, a difference Δf between a frequency on the approximate equation and the actually measured frequency at each measured temperature was obtained with the respective piezoelectric devices. A value Δf/F (hereinafter this is referred to as a Frequency dips, unit: ppm) found by dividing this Δf by an oscillation frequency F was obtained. Next, average values and standard deviations σ of the thus obtained Frequency dips of each 60 pieces of Comparative Example, Working Example 1, and Working Example 2 were obtained at each measured temperature.

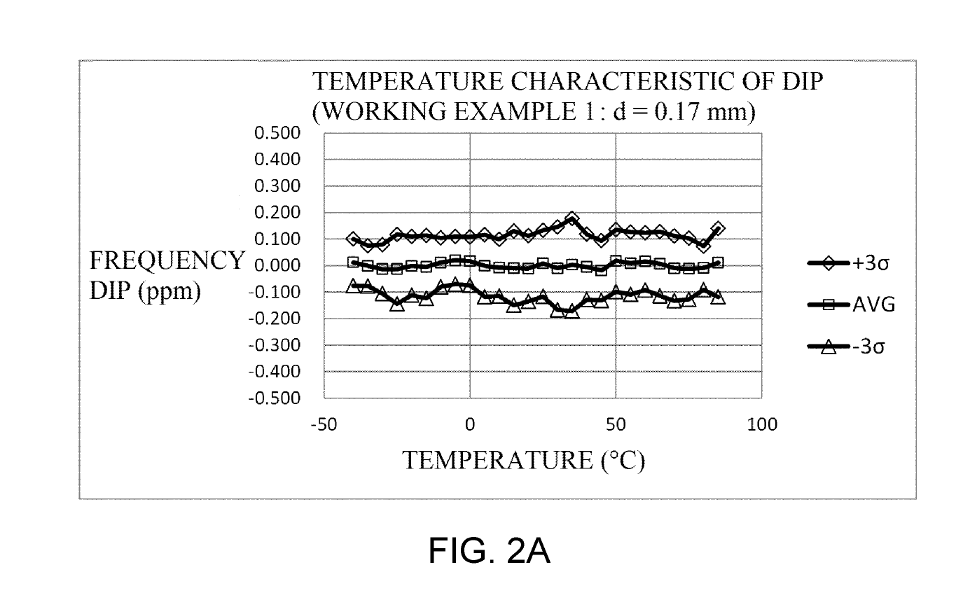

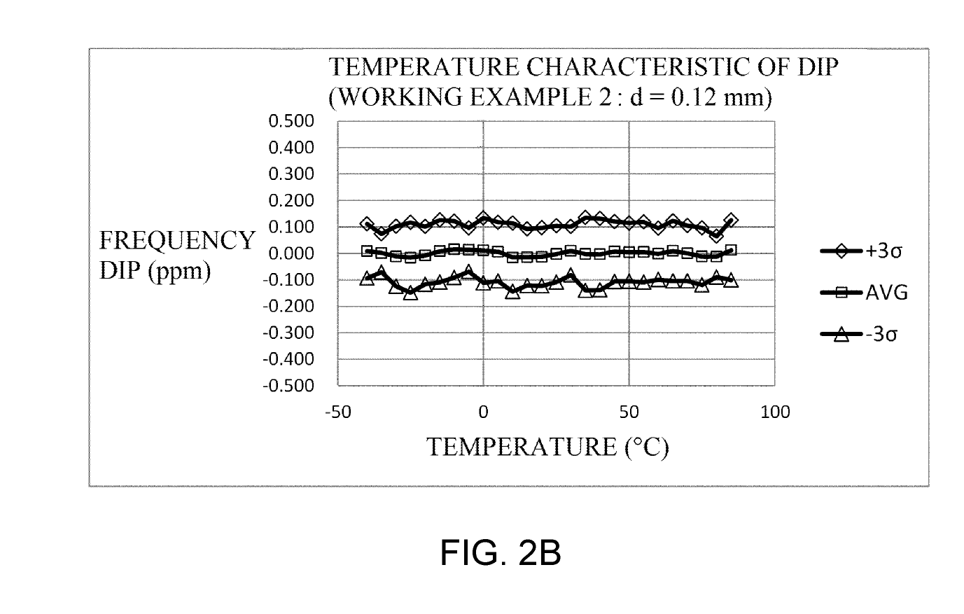

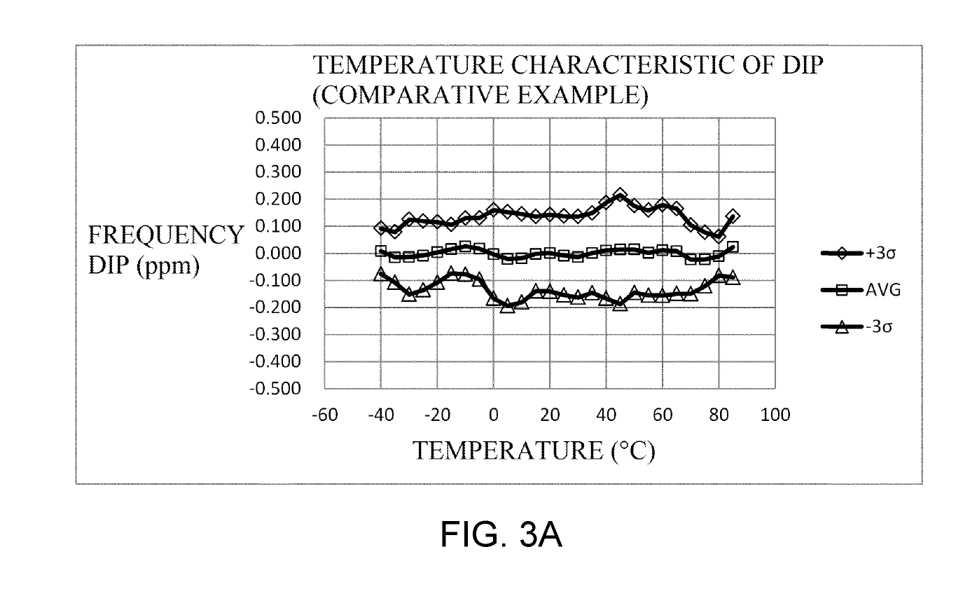

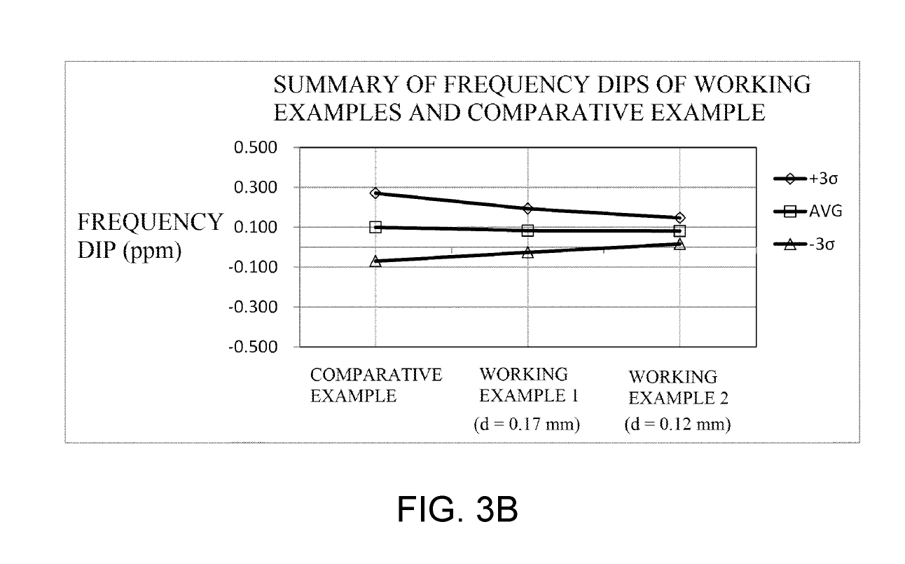

FIG. 2A is a characteristic diagram that plots an average value, an average value +3σ, and an average value −3σ of the Frequency dips of 60 pieces of the piezoelectric devices of Working Example 1 obtained above with the temperature (° C.) on the horizontal axis and the Frequency dips (ppm) on the vertical axis. The drawing denotes the average value as AVG, the average value +3σ as +3σ, and the average value −3σ as −3σ. FIG. 2B is a characteristic diagram of 60 pieces of the piezoelectric devices of Working Example 2 created similar to FIG. 2A. FIG. 3A is a characteristic diagram of 60 pieces of the piezoelectric devices of Comparative Example created similar to FIG. 2A.

It has been found through the comparison between FIG. 2A, FIG. 2B, and FIG. 3A that Working Example 1 and Working Example 2, which include the unnecessary vibration suppression electrodes, can reduce the Frequency dips compared with the case of Comparative Example that does not include the unnecessary vibration suppression electrode. Furthermore, it has been found that Working Example 2 providing the smaller distance between the unnecessary vibration suppression electrodes and the excitation electrodes can further reduce the Frequency dips compared with Working Example 1.

For easier understanding of the differences between Comparative Example, Working Example 1, and Working Example 2, the Frequency dips largest in the entire temperature characteristic measurement range were extracted from each of 60 pieces of samples of Comparative Example, Working Example 1, and Working Example 2 to obtain these average values and ±3σ. That is, the maximum Frequency dips of the sample 1 in a range of −40° C. to +85° C. . . . and similarly the maximum Frequency dips of the sample 60 were extracted to obtain the average values and ±3σ from the values. The following Table 1 and FIG. 3B show the results.

TABLE 1

| | Comparative | Working example 1 | Working example 2 |
|---|---|---|---|
| | example | (d = 0.17 mm) | (d = 0.12 mm) |
| +3σ | 0.270 | 0.192 | 0.147 |
| AVG | 0.100 | 0.083 | 0.081 |
| −3σ | −0.070 | −0.026 | 0.016 |

Unit: ppm

It has been found from Table 1 and FIG. 3B that a level of improvement in the Frequency dips is Working Example 2>Working Example 1>Comparative Example. In detail, the following has been found. In the case of Working Example 1 with the distance between the unnecessary vibration suppression electrodes and the excitation electrodes of 0.17 mm, the Frequency dips fall within the range of +0.192 ppm to −0.026 ppm at +3σ. Additionally, in the case of Working Example 2 with the distance between the unnecessary vibration suppression electrodes and the excitation electrodes of 0.12 mm, the Frequency dips further fall within the range of +0.147 ppm to +0.016 ppm at ±3σ. Therefore, it can be understood that the unnecessary vibration suppression electrode contributes to the improvement in the Frequency dip. From the above-described results, it has been found that the smaller distance between the unnecessary vibration suppression electrodes and the excitation electrodes is preferable. A proper value of this distance will be described later. The extent that the distance between the unnecessary vibration suppression electrodes and the excitation electrodes can be decreased mainly relates to manufacturing technology elements. For example, to form the excitation electrode, the extraction electrode, and the unnecessary vibration suppression electrode using a plating frame, the distance can be decreased down to around 0.05 mm currently. A patterning technique by a photolithography technique can decrease the distance further.

The reasons that disposing the unnecessary vibration suppression electrode can reduce the Frequency dips are estimated as follows. Even if the generated unnecessary vibration attempts to reflect and return to the excitation electrode after the unnecessary vibration propagates the extraction electrode and reaches the end portion of the piezoelectric substrate, the unnecessary vibration suppression electrode can suppress this reflection. Even if the unnecessary vibration generates unexpected electric charges on the piezoelectric substrate, the electric charges flow to a site other than a vibrator via the unnecessary vibration suppression electrode and the conductive adhesive.

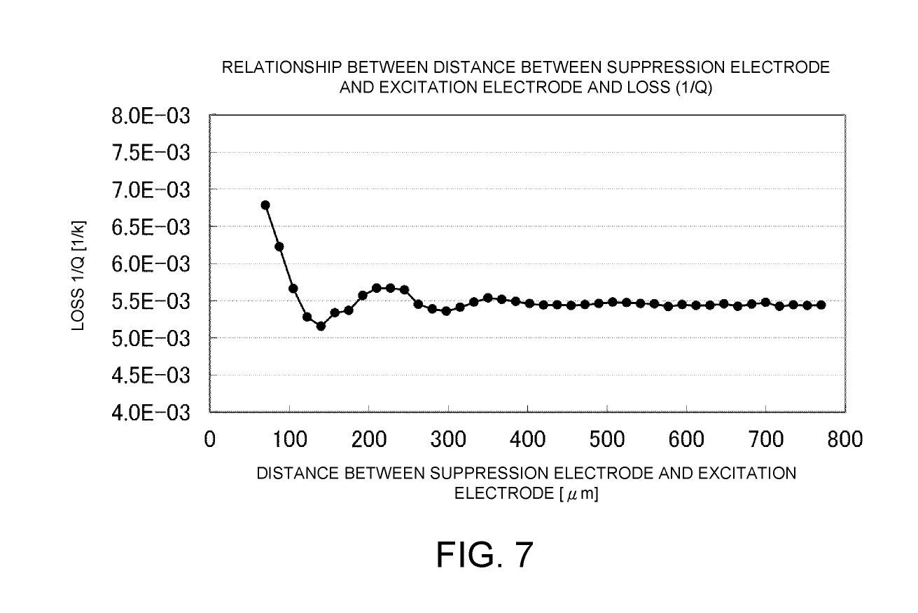

The following describes results through examinations on the proper value of the distance d1 (d2) between the unnecessary vibration suppression electrode and the excitation electrode. Specifically, the inventor simulated how the loss of the piezoelectric device varied when the distance d1 was changed by a finite element method and examined the proper value of the distance d1 (d2). A used model is a model configured as the AT-cut quartz substrate (i.e., piezoelectric substrate 11) with a long side of 3.2 mm and a short side of 1.8 mm, and as the excitation electrodes 13a and 13c with a long side of 0.88 mm and a short side of 0.85 mm. Note that, in the model, the excitation electrodes were disposed on the piezoelectric substrate such that the centers of the excitation electrodes matched the center of the piezoelectric substrate. Unnecessary vibration suppression electrodes were disposed on a side of the first-side 11x (see FIG. 1A) of the piezoelectric substrate 11. Assuming the models where the distances d1 (d2) between these suppression electrodes and excitation electrodes were variously differentiated, the loss (1/Q) at each model (piezoelectric device) was calculated by the finite element method. Regarding the loss (1/Q) of the respective models, all the models exhibited the maximum value near −30 degrees; therefore, the maximum losses near this temperature were used as a measure of the central tendency of the loss of each model to create FIG. 7.

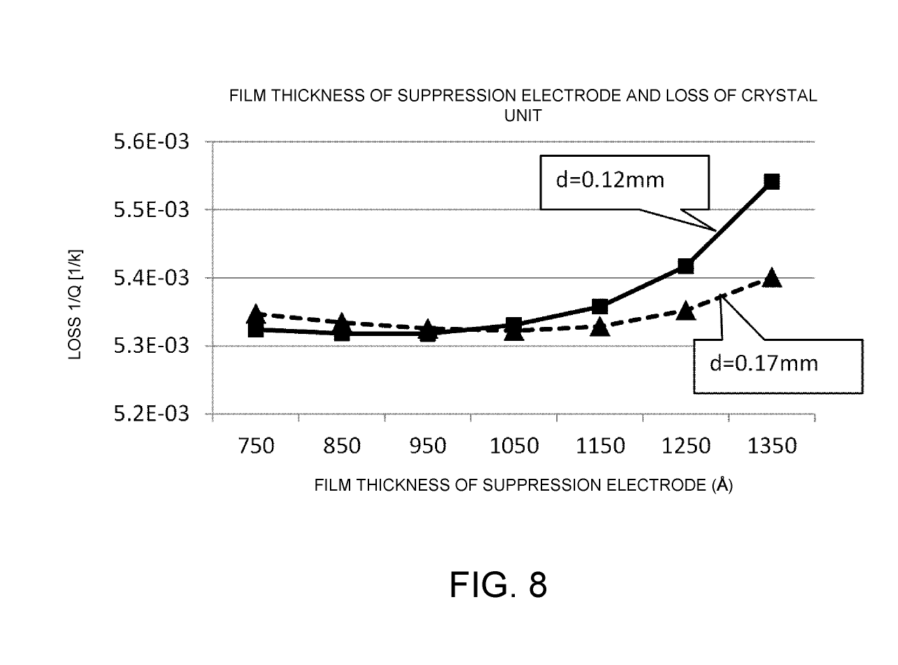

FIG. 7 is a drawing illustrating the relationship between the distance d1 (d2) and the loss (1/Q) with the distance d1 (d2) on the horizontal axis and the loss (1/Q) on the vertical axis. The 1/k for the loss 1/Q (1/k) is an abbreviation for 10 to the negative third power (the same applies to FIG. 8 described later).

As apparent from FIG. 7, too small distance d1 (d2) increases the loss (1/Q), the loss becomes the local minimal value with the distance d1 (d2) in the proper range, and the further increased distance d1 (d2) worsens the loss, and then the loss becomes nearly flat. Specifically, with the above-described model, the loss increases with the distance d1 (d2) of 105 μm or less, the loss decreases with the distance in a range of 110 μm to 175 μm. Besides, the loss becomes the local minimal value with the distance d1 (d2) near 140 μm (namely, 0.14 mm), and the distance larger than 175 μm worsens the loss, and then the loss becomes nearly flat. Therefore, the distance d1 (d2) is preferably 110 μm to 170 μm (namely, 0.11 mm to 0.17 mm).

### 3. Second, Third, Fourth, and Fifth Embodiments of First Aspect

This embodiment is not limited to the first embodiment but is also applicable to various kinds of structures as described later. The following describes the embodiments in order.

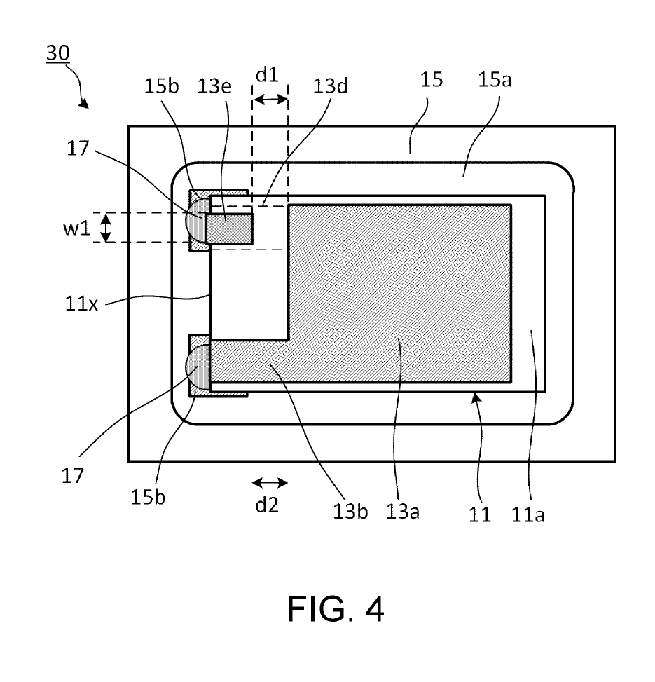

FIG. 4 is a drawing describing a piezoelectric device 30 according to the second embodiment, illustrating the piezoelectric device 30 in a plan view similar to FIG. 1A. While the piezoelectric device 10 of the first embodiment includes the two unnecessary vibration suppression electrodes, the piezoelectric device 30 according to the second embodiment is an example of including only one unnecessary vibration suppression electrode. FIG. 4 illustrates an example of disposing the first unnecessary vibration suppression electrode 13e described in the piezoelectric device 10 according to the first embodiment.

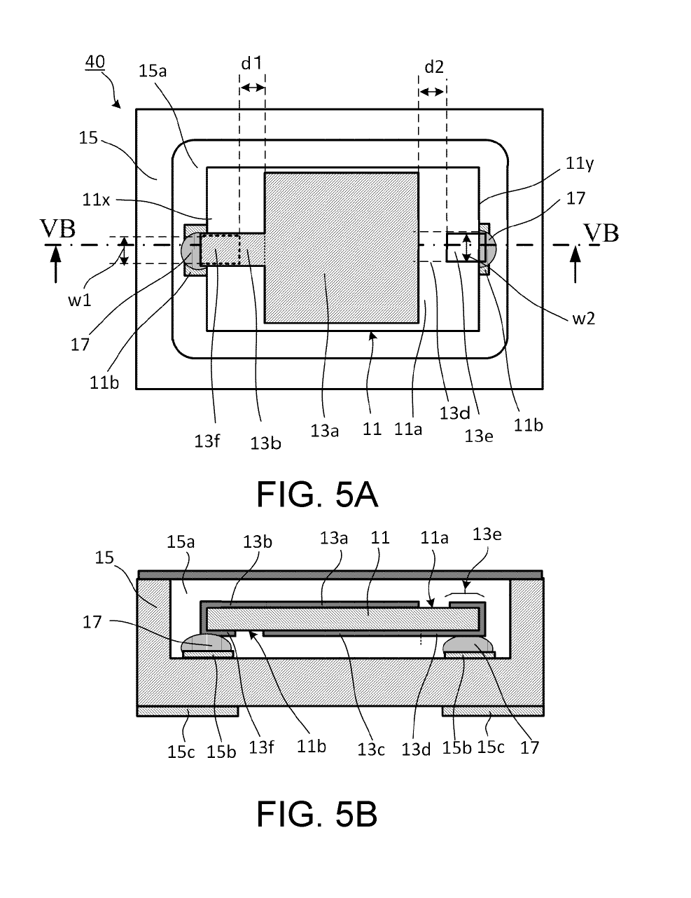

FIG. 5A and FIG. 5B are drawings describing a piezoelectric device 40 according to the third embodiment. Especially, FIG. 5A is a plan view of the piezoelectric device 40, and FIG. 5B is a cross-sectional view taken along a line VB-VB in FIG. 5A.

This piezoelectric device 40 according to the third embodiment is an example of applying this embodiment to what is called a piezoelectric device with a doubly supported structure. That is, with this piezoelectric device 40, the first extraction electrode 13b is extracted to a side of the first-side 11x of the piezoelectric substrate 11, and the second extraction electrode 13d is extracted to a side of a second-side 11y, which is opposed to the first-side 11x, of the piezoelectric substrate 11. The piezoelectric substrate 11 is doubly held on the side of the first-side 11x and the side of the second-side side 11y. Accordingly, the first unnecessary vibration suppression electrode 13e and the second unnecessary vibration suppression electrode 13f are disposed at the positions facing the respective extraction electrodes extracted to handle the doubly supported structure. The distances d1 and d2, the widths w1 and w2, and a similar specification are selectable similar to the first embodiment. This embodiment is also applicable to the piezoelectric device with the doubly supported structure, thereby ensuring obtaining the effects of this embodiment.

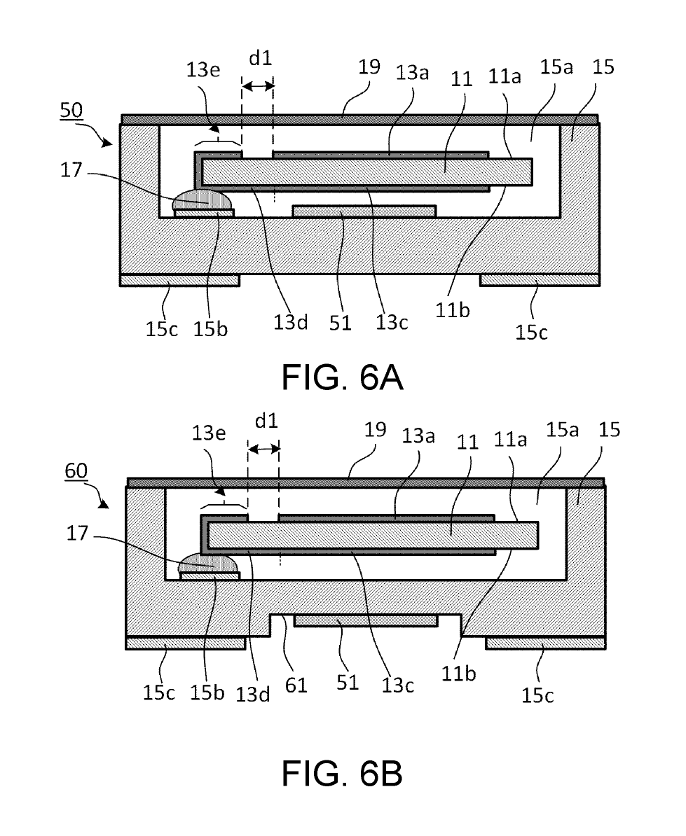

FIG. 6A is a drawing describing a piezoelectric device 50 according to the fourth embodiment, illustrating the piezoelectric device 50 by a cross-sectional view similar to FIG. 1B. This piezoelectric device 50 according to the fourth embodiment is an example of a piezoelectric device as an oscillator that adds an oscillator circuit for this piezoelectric device to the piezoelectric device described above. Especially, this piezoelectric device 50 includes an oscillator circuit 51 at a bottom surface of the depressed portion 15a of the container 15. Here, the oscillator circuit is various kinds of circuits such as a highly functional circuit including the oscillator circuit, a circuit to guarantee the temperature, and a similar circuit in the case of the oscillator circuit alone.

FIG. 6B is a drawing describing a piezoelectric device 60 according to the fifth embodiment, illustrating the piezoelectric device 60 by a cross-sectional view similar to FIG. 1B. While the piezoelectric device according to the fourth embodiment includes the oscillator circuit 51 at the bottom surface of the depressed portion 15a of the container 15, this piezoelectric device 60 according to the fifth embodiment is an example that has a depressed portion 61on its back surface side for the oscillator circuit on the back surface side of the container 15 and includes the oscillator circuit 51 in this depressed portion 61. These piezoelectric devices 50 and 60 achieve the oscillator exhibiting the frequency versus temperature characteristic more excellent compared with the conventional piezoelectric devices.

### 4. Second Aspect and Third Aspect (Regarding Film Thickness of Unnecessary Vibration Suppression Electrode)

The first aspect conducted the examination using the excitation electrodes and the unnecessary vibration suppression electrodes with the identical film thickness. However, the inventor has proved the following through the examination. Designing the film thickness of the unnecessary vibration suppression electrodes to have a predetermined film thickness different from the film thickness of the excitation electrodes allows changing the suppression effect of the unnecessary vibration. The following describes this point.

From the simulation model used in the first aspect, a first model with the film thickness of the excitation electrodes of 950A and the distance between the unnecessary vibration suppression electrodes and the excitation electrodes of 0.12 mm, and a second model similar to the first model except that the distance being 0.17 mm were prepared. The loss of these two kinds of respective models (piezoelectric devices) when the film thicknesses of the unnecessary vibration suppression electrodes were changed from 750 Å to 1350 Å in increments of 100 Å was calculated by the finite element method.

FIG. 8 is a drawing illustrating the relationship between the film thickness of the unnecessary vibration suppression electrodes and the loss (1/Q) with the film thickness on the horizontal axis and the loss (1/Q) on the vertical axis.

As apparent from FIG. 8, changing the film thickness of the unnecessary vibration suppression electrodes changes the loss of the piezoelectric devices. In view of this, it has been found that changing the film thickness of the unnecessary vibration suppression electrodes can adjust the suppression effect of the unnecessary vibration. Differentiating the distance between the unnecessary vibration suppression electrodes and the excitation electrodes differentiates the relationship between the film thickness of the unnecessary vibration suppression electrodes and the loss of the piezoelectric devices. That is, in the case of these two models, it has been found that the smaller the distance between the unnecessary vibration suppression electrodes and the excitation electrodes (the case of 0.12 mm), the larger the change in the loss of the piezoelectric devices in association with the increase in the film thickness of the unnecessary vibration suppression electrodes. As apparent from FIG. 8, the loss decreases in the case where the film thickness of unnecessary vibration suppression electrodes is the same extent to the film thickness of the excitation electrodes. That is, with these simulation models, the film thickness of the unnecessary vibration suppression electrodes is around 950 Å±200 Å, which is the film thickness of the excitation electrodes, in other words, ±20% of the film thickness of the excitation electrodes, preferably ±10%.

Meanwhile, the following can also be said from the results in FIG. 8. It has been found that, with the distance between the excitation electrodes and the unnecessary vibration suppression electrodes of 0.12 mm, the film thickness of the unnecessary vibration suppression electrodes with which the loss of the piezoelectric device can be the local minimum is near 950 Å. Similarly, with the distance between the excitation electrodes and the unnecessary vibration suppression electrodes of 0.17 mm, the film thickness of the unnecessary vibration suppression electrodes with which the loss can be the local minimum may be around 950 Å to 1100 Å. This means that, increasing in the distance between the excitation electrodes and the unnecessary vibration suppression electrodes and thickening the film thickness of the unnecessary vibration suppression electrodes more than the film thickness of the excitation electrodes can obtain the reduction effect of the loss of the piezoelectric device similar to the case where the distance between the excitation electrodes and the unnecessary vibration suppression electrodes is decreased. To decrease the distance between the excitation electrodes and the unnecessary vibration suppression electrodes, mechanical accuracy of the plating frame while the electrodes are created needs to be enhanced. To avoid this, a method that configures the distance to, for example, 0.17 mm and thickens the film thickness of the unnecessary vibration suppression electrodes by, for example, forming films twice at the parts of the unnecessary vibration suppression electrodes can also be employed.

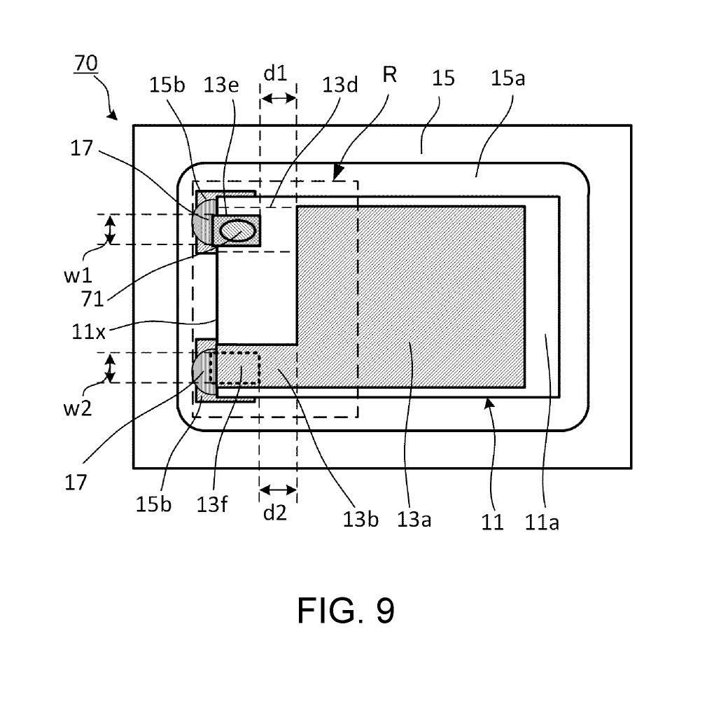

Further, the following method can also be employed. The films are intentionally formed on the parts of the unnecessary vibration suppression electrodes twice in advance to thicken the film thickness of the unnecessary vibration suppression electrodes more than the excitation electrodes. Afterwards, this thickened parts are selectively removed using, for example, ion of argon gas and, for example, adjustment is performed such that the loss of the piezoelectric device becomes a desired value, which is, namely, a third aspect. FIG. 9 is an explanatory drawing of the third aspect. That is, a piezoelectric device 70 of this third aspect includes an unnecessary vibration adjustment mark 71 generated through the adjustment of the loss of the piezoelectric device to the desired value on the surface of the unnecessary vibration suppression electrode 13e. Since the piezoelectric device 70 illustrated in FIG. 9 is an SMD type piezoelectric device, the unnecessary vibration adjustment mark 71 is formed on the unnecessary vibration suppression electrode 13e on the first principal surface lla side of the piezoelectric substrate 11. Meanwhile, with the piezoelectric device of a lead type or a similar type, the unnecessary vibration adjustment marks 71 can be generated on the unnecessary vibration suppression electrodes on both principal surfaces of the piezoelectric substrate 11.

### 5. Fourth Aspect (Regarding Addition of Different-Kind-of-Material)

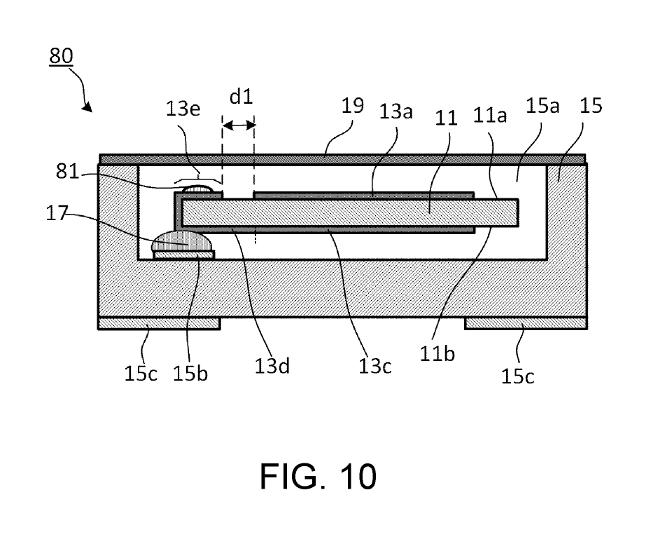

While the above-described respective aspects examine the position and the film thickness of the unnecessary vibration suppression electrode to the excitation electrode, further examinations by the inventor has proved that providing the different-kind-of-material on the surface of the unnecessary vibration suppression electrode changes the unnecessary vibration suppression effect. The following describes an embodiment of this example (the fourth aspect). FIG. 10 is a cross-sectional view describing a piezoelectric device 80 of this fourth aspect, a cross-sectional view corresponding to FIG. 1B.

This piezoelectric device 80 enhances the unnecessary vibration suppression effect by disposing a different-kind-of-material 81 on the surface of the unnecessary vibration suppression electrode 13e. Any given preferable material is applicable as the different-kind-of-material 81. Typically, an adhesive is applicable. Any given preferable adhesive is applicable as the adhesive, may be non-conductive or conductive. Note that, taking a simplification of the process and a similar matter into consideration, utilizing the conductive adhesive 17 used to connect the piezoelectric substrate 11 with the container 15 is preferable.

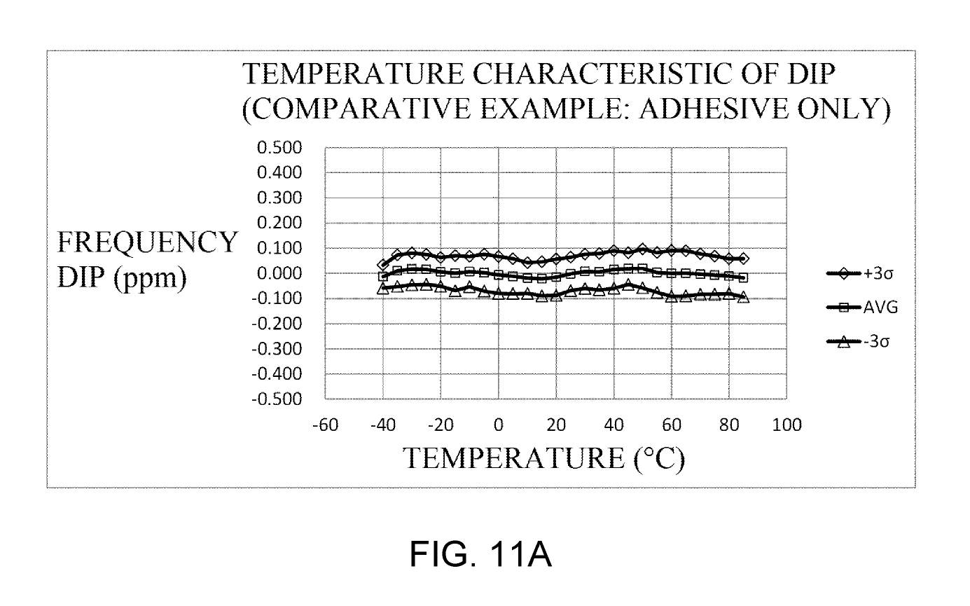

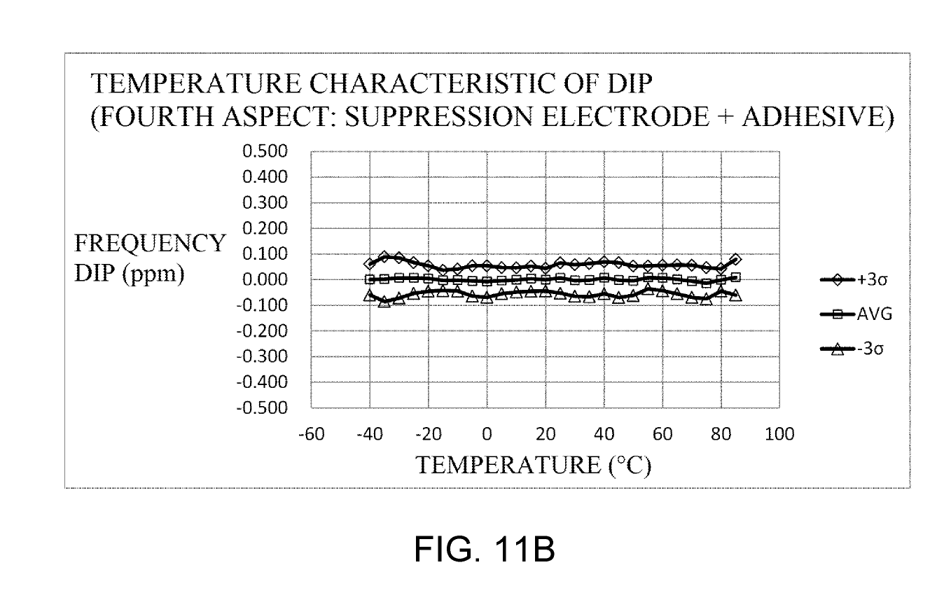

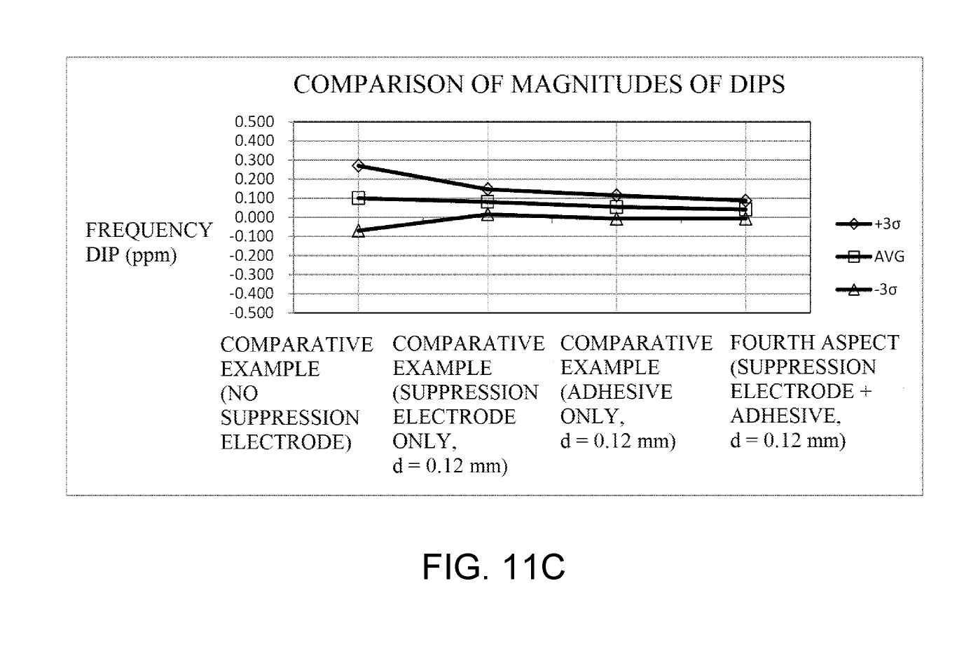

The following describes effects brought by disposing this different-kind-of-material 81. As Comparative Example, 60 pieces of piezoelectric devices that did not include the unnecessary vibration suppression electrode but included the conductive adhesive at the position were prototyped. As Working Example of the fourth aspect, 60 pieces of the piezoelectric devices 80 that included the unnecessary vibration suppression electrode 13e described with reference to FIG. 10 and the different-kind-of-material 81 using the conductive adhesive disposed on the unnecessary vibration suppression electrode 13e were prototyped. Similarly to the case described in the section of the first aspect, the frequency versus temperature characteristic of the piezoelectric devices of these Comparative Example and Working Example was measured to calculate Frequency dip. FIG. 11A illustrates the Frequency dips of Comparative Example, and FIG. 11B illustrates the Frequency dips of Working Example. The method of summarizing data and a similar method are identical to the method described with reference to FIG. 2A and FIG. 2B and FIG. 3A and FIG. 3B in the first aspect; therefore, the explanation is omitted.

The following Table 2 and FIG. 11C summarize and organize the properties of the Frequency dips of these Comparative Example and Working Example and properties of the respective Frequency dips of Comparative Example that does not include the unnecessary vibration suppression electrode described in the first aspect and Comparative Example that includes the unnecessary vibration suppression electrode (this is equivalent to Working Example in the first aspect). In any standard, a distance between the unnecessary vibration suppression electrode and the excitation electrode was configured to be 0.12 mm.

TABLE 2

| | | Comparative example | | Fourth aspect |
|---|---|---|---|---|
| | Comparative example | (Suppression electrode | Comparative example | (Suppression electrode + |
| | (No suppression electrode) | only, d = 0.12 mm) | (Adhesive only, d = 0.12 mm) | Adhesive, d = 0.12 mm) |
| +3σ | 0.270 | 0.147 | 0.115 | 0.087 |
| AVG | 0.100 | 0.081 | 0.054 | 0.041 |
| −3σ | −0.070 | 0.016 | −0.007 | −0.006 |

Unit: ppm

It has been found from Table 2 and FIG. 11C that the level of improvement in the Frequency dips is the fourth aspect>Comparative Example (the adhesive only) Comparative Example (the suppression electrode only)>Comparative Example (no suppression electrode). That is, it has been found that the fourth aspect enhances the unnecessary vibration suppression effect compared with the other standards. However, the configuration that adds a different-kind-of-material such as the adhesive on the unnecessary vibration suppression electrode takes a labor by the addition of the different-kind-of-material. Accordingly, selectably using the respective structures of the first to the fourth aspects according to the specifications required for the piezoelectric device is preferable. Doing so ensures obtaining a desired piezoelectric device according to the required specifications for the piezoelectric device.

As described using FIG. 4, similar to the first aspect, the second to the fourth aspects may include only one of the unnecessary vibration suppression electrodes. Additionally, as described using FIG. 5A and FIG. 5B, the aspects are applicable to the piezoelectric device with the doubly supported structure. Further, as illustrated in FIG. 6A and FIG. 6B, the aspects are applicable to the piezoelectric device including the oscillator circuit.

A piezoelectric device according to a second aspect of this application in the above-described piezoelectric device according to the first aspect is configured as follows. The provided unnecessary vibration suppression electrodes in the configuration of the first aspect have a predetermined film thickness different from a film thickness of the excitation electrodes on planar surfaces identical to the unnecessary vibration suppression electrodes.

A piezoelectric device according to a third aspect of this application in the above-described first aspect or the second aspect further includes an unnecessary vibration suppression adjustment mark on a surface of the provided unnecessary vibration suppression electrode.

A piezoelectric device according to a fourth aspect of this application further includes a different-kind-of-material on the unnecessary vibration suppression electrode provided with the piezoelectric device according to the above-described first aspect, the second aspect, or the third aspect.

As the different-kind-of-material, for example, an adhesive is preferable and further a conductive adhesive is preferable as the adhesive.

To embody these aspects, the piezoelectric device may have both the so-called cantilever structure that holds the piezoelectric substrate by two sites on the one end side and the so-called doubly supported structure that holds the piezoelectric substrate by both opposed ends. Further, a piezoelectric device as an oscillator that additionally includes an oscillator circuit to any one of the respective configurations may be included in the piezoelectric device of this disclosure.

With the piezoelectric device according to the first aspect, the unnecessary vibration suppression electrodes are disposed on the predetermined regions of the piezoelectric substrate. Therefore, compared with the case where the unnecessary vibration suppression electrodes are not disposed, the Frequency dips in the frequency versus temperature characteristic can be reduced as apparent from the experimental results described above. The unnecessary vibration suppression electrodes have a feature such as being configured to be integrally formed in the case where the excitation electrodes are formed. Therefore, compared with the case where the adhesive is applied for weighting, the unnecessary vibration suppression electrodes can be accurately disposed on the piezoelectric substrate. Accordingly, for example, deterioration of the original property of the piezoelectric device, for example, crystal impedance is less likely to occur.

With the piezoelectric device according to the second aspect, the film thickness of the unnecessary vibration suppression electrodes is the predetermined film thickness different from the film thickness of the excitation electrodes; therefore, compared with the case where the unnecessary vibration suppression electrodes are simply configured with the thin film similar to the excitation electrodes, the unnecessary vibration can be accurately reduced.

With the piezoelectric device according to the third aspect, the unnecessary vibration adjustment mark is provided on the surface of the unnecessary vibration suppression electrode; therefore, compared with the case where the unnecessary vibration suppression electrode is simply configured with the thin film similar to the excitation electrode, the unnecessary vibration can be accurately reduced.

With the piezoelectric device according to the fourth aspect, since the different-kind-of-material such as the adhesive can be additionally provided on the unnecessary vibration suppression electrode; therefore, compared with the case where the unnecessary vibration suppression electrode is simply configured with the thin film similar to the excitation electrode, the unnecessary vibration can be accurately reduced.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A piezoelectric device that vibrates in a thickness-shear vibration mode, comprising:
a piezoelectric substrate;
a first excitation electrode, disposed on a first principal surface of the piezoelectric substrate;
a first extraction electrode, extracted from the first excitation electrode to an end of the piezoelectric substrate;
a second excitation electrode, disposed on a second principal surface opposed to the first principal surface of the piezoelectric substrate;
a second extraction electrode, extracted from the second excitation electrode to another end of the piezoelectric substrate; and
a container that houses the piezoelectric substrate,
wherein the piezoelectric device further includes:
a first unnecessary vibration suppression electrode, disposed on a region of the first principal surface opposed to the second extraction electrode, the first unnecessary vibration suppression electrode being disposed at a region separated from the first excitation electrode by a distance d1, the first unnecessary vibration suppression electrode having an electric potential identical to the second excitation electrode; and/or
a second unnecessary vibration suppression electrode, disposed on a region of the second principal surface opposed to the first extraction electrode, the second unnecessary vibration suppression electrode being disposed at a region separated from the second excitation electrode by a distance d2, the second unnecessary vibration suppression electrode having an electric potential identical to the first excitation electrode;
wherein in a case where the first unnecessary vibration suppression electrode and the second unnecessary vibration suppression electrode are both provided, the distance d1 and the distance d2 are identical or different.

2. The piezoelectric device according to claim 1, wherein
the piezoelectric substrate has a planar shape of a square shape,
the first extraction electrode is extracted to one end side on a first-side of the piezoelectric substrate,
the second extraction electrode is extracted to another end side on the first-side of the piezoelectric substrate, and
the piezoelectric substrate is held in a cantilever manner by a side of the first-side.

3. The piezoelectric device according to claim 1, wherein
the piezoelectric substrate has a planar shape of a square shape,
the first extraction electrode is extracted to a first-side side of the piezoelectric substrate,
the second extraction electrode is extracted to a second-side side of the piezoelectric substrate, the second-side being opposed to the first-side, and
the piezoelectric substrate is doubly held by a side of the first-side and a side of the second-side.

4. The piezoelectric device according to claim 1, wherein
the distances d1 and d2 are configured to be 0.17 mm or less.

5. The piezoelectric device according to claim 1, wherein
the distances d1 and d2 are configured to be 0.11 mm or more and 0.17 mm or less.

6. The piezoelectric device according to claim 1, wherein
the first unnecessary vibration suppression electrode has a predetermined film thickness different from a film thickness of the first excitation electrode on a planar surface identical to the first unnecessary vibration suppression electrode;
the second unnecessary vibration suppression electrode has a predetermined film thickness different from a film thickness of the second excitation electrode on a planar surface identical to the second unnecessary vibration suppression electrode.

7. The piezoelectric device according to claim 1, further comprising:
an unnecessary vibration suppression adjustment mark, being disposed on a surface of at least one of the first unnecessary vibration suppression electrode and the second unnecessary vibration suppression electrode.

8. The piezoelectric device according to claim 1, further comprising:
a different-kind-of-material, being disposed on at least one of the first unnecessary vibration suppression electrode and the second unnecessary vibration suppression electrode.

9. The piezoelectric device according to claim 8, wherein
the different-kind-of-material is a conductive adhesive.

10. The piezoelectric device according to claim 1, further comprising:
an oscillator circuit for the piezoelectric device, being disposed at the container.
